(19) United States
(12) Patent Application Publication
(10) Pub. No.: US 2011/0298345 A1
(43) Pub. Date: Dec. 8, 2011

(54) PORTABLE ELECTRONIC DEVICE CASE WITH CLEANING ACCESSORY

(75) Inventors: Robert Shortt, Laguna Beach, CA (US); Kevin Gallagher, Los Angeles, CA (US)

(73) Assignee: TARGUS GROUP INTERNATIONAL, INC., Anaheim, CA (US)

(21) Appl. No.: 13/155,188

(22) Filed: Jun. 7, 2011

Related U.S. Application Data
(60) Provisional application No. 61/352,286, filed on Jun. 7, 2010.

(51) Int. Cl. H05K 5/02

(52) U.S. Cl. 312/237

(57) ABSTRACT

A case accessory for a portable electronic device that includes a cleaning system is disclosed. In some embodiments, the case accessory may include a back cover configured to secure a portable electronic device, a front cover rotationally coupled to the back cover, and a cleaning mechanism integrated into the front cover including a buffer configured to clean a surface of the portable electronic device.

### RELATED APPLICATIONS

This application claims priority under 35 U.S.C. §119(e) to U.S. Provisional Patent Application No. 61/352,286, filed Jun. 7, 2010, and entitled “ELECTRONIC READER CASES AND RELATED SYSTEMS AND METHODS,” which is herein incorporated by reference in their entireties.

### TECHNICAL FIELD

The present disclosure relates generally to portable electronic devices and, more specifically, to case accessories for portable electronic devices.

### BRIEF DESCRIPTION OF THE DRAWINGS

The written disclosure herein describes illustrative embodiments that are non-limiting and non-exhaustive. Reference is made to certain of such illustrative embodiments that are depicted in the figures, in which:

FIG. 1 illustrates a front perspective view of a case for a for a portable electronic device that includes a cleaning system consistent with embodiments of the present disclosure; and

FIG. 2 illustrates a front perspective view of the case illustrated in FIG. 1 in a closed configuration consistent with embodiments of the present disclosure.

### DETAILED DESCRIPTION

The proliferation of portable electronic devices (PEDs), including notebook and tablet computers (e.g., the Apple® iPad™), portable digital assistants (PDAs), and smartphones, has placed more computing power into the hands of users than the computing power of early computers that occupied an entire room. This portable computing power has enhanced both personal and business mobile productivity.

Due to their portability, however, PEDs may be susceptible to collecting particulates (i.e., becoming dirty) from continued use and/or transport. In certain circumstances, particulates collected over time on a display of a PED may decrease the usability of the display. For example, a display may become less viewable over time due to particulate buildup. Similarly, in the context of a touch screen display, the display may become less responsive due to particulates being deposited on the display.

Embodiments of the present disclosure provide an accessory case for a PED that includes a cleaning system. In some embodiments, the accessory case may be configured to secure, retain, and protect the PED from external damage. Further, in various embodiments, the case may include a system for cleaning at least one surface of a PED that for certain PEDs, may include a display.

Embodiments may be best understood by reference to the drawings. In certain instances, like features may be designated with like reference numerals. It will be readily understood that the components of the present disclosure, as generally described and illustrated in the drawings herein, could be arranged and designed in a wide variety of different configurations. Thus, the following more detailed description of the embodiments of the apparatus is not intended to limit the scope of the disclosure, but is merely representative of possible embodiments of the disclosure. In some cases, well-known structures, materials, or operations are not shown or described in detail.

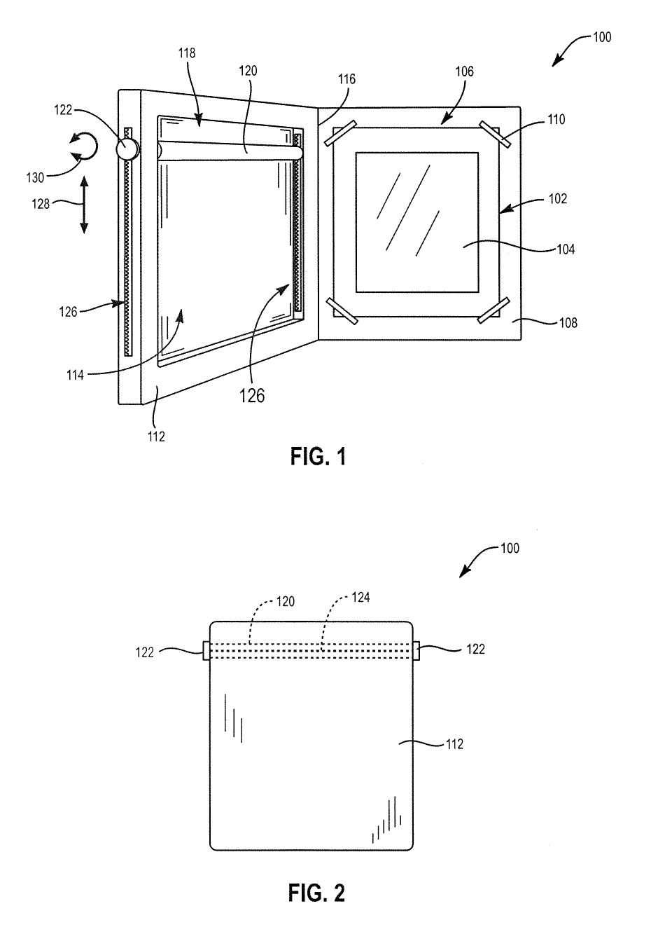

FIGS. 1-2 illustrate a case 100 for a for a PED 102 that includes a cleaning system 118 consistent with embodiments of the present disclosure. The illustrated case 100 may be referred to as a holder, sleeve, mount, and the like and, as used herein, does not necessarily imply an encasing or retaining functionality, although some embodiments of the case 100 may have such functionalities. The PED 102 may be any portable electronic device including, for example, a notebook computer, an electronic book reader (e.g., the Amazon® Kindle™), a ® ® ® smartphone (e.g., the Apple® iPhone™, the Motorola® Droid®, and the BlackBerry® Storm™) and/or a tablet computer (e.g., the Apple® iPad™, the HP® Slate, and the Samsung® Galaxy™ Tablet).

The case 100 can be configured to receive a PED 102, and may further function to retain, carry, and protect the PED 102. The PED 102 can include on the front and/or the back face of the PED 102 a display 104 that is viewable in either a portrait orientation or a landscape orientation, a user input (not shown), and a data input/output port (not shown). In some embodiments, the case 100 may be configured such that the display 104, user input, and data input/output port are accessible by a user of the PED 102 while the PED 102 is disposed in the case 100. Further, in some embodiments, the case 100 may include a protective cover and/or screen disposed over the display 104.

In certain embodiments, the components of the case 100 may be formed of one or more suitable materials (e.g., plastic, leather, etc.) and may be durable and/or hard where appropriate so as to protect the PED 102 from external damage. In further embodiments, the components of the case 100 that are in contact with the PED 102 may be formed of soft materials (e.g., fabric, microfiber, suede) or other suitable materials so as to protect the surface of the PED 102 from scratches and/or other damage.

The case 100 may include a holder 106. As illustrated, the holder 106 may comprise a back cover 108 and one or more connectors 110 configured to secure the PED 102 to the back cover 108. In the illustrated embodiments, the connectors 110 comprise resilient straps that, in certain embodiments, may be elastic. When the PED 102 is secured, the connectors 110 may be configured to be spaced from the display 104 so as to not cover or obstruct the display 104. In other embodiments, the PED 102 may be secured to the back cover 108 using a ratcheting swivel or pivot mechanism, a rotating grommet mechanism, a ball and socket mechanism, a temporary or permanent adhesive, a releasable latch, a clip, one or more buttons, a suction cup, and/or any other securement mechanism. In certain embodiments, the PED 102 may be secured using a mechanism allowing the PED 102 to selectively detach from the holder 106 using, for example, a two part selectively detachable rotating grommet or the like.

In some embodiments, the back cover 108 can cover at least a portion of a rear surface of the PED 102 and may comprise a hard and protective material. The case 100 can further include a front cover 112, which likewise may comprise a hard and protective material. The front and back covers 112, 108 can be connected in any suitable manner, such as via a hinge 116. In certain embodiments, the front and back covers 112, 108 may be integral components and may rotate in one or more directions relative to each other via an integrated fold. In some embodiments, the front cover 112 may define a cavity 114 that is sized to receive at least a front face of the PED 102 therein when the case 100 is in a closed or stowage configuration wherein the front cover 112 and the back cover 108 are closed about the hinge 116.

Consistent with certain embodiments, the front cover 112 may include a cleaning mechanism 118. In certain embodiments, the cleaning mechanism 118 may be configured to clean a surface of the PED 102 and/or display 104 when the case 100 is in a closed or stowage configuration. In some embodiments, to place the case 100 in a closed or stowage configuration, the front cover 112 may be rotated about the hinge 116 such that the front cover 112 is substantially parallel to the back cover 108. In a closed configuration, the PED 102 and/or display may be protected from external damage by the back cover 108 and the front cover 112.

In various embodiments, the cleaning mechanism 118 may include a buffer 120 having a rod 124 disposed therein. In some embodiments, the rod 124 may provide a rigid structure to the buffer 120 and maintain the buffer 120 in a substantially linear shape. The buffer 120 and/or rod 124 may be coupled to one or more actuators 122. As illustrated, the buffer 120 and/or rod 124 may be positioned within the cavity 114 defined by the front cover 112, and the actuators 122 may be positioned at one or more sides of the front cover 112. In the illustrated embodiments, the actuators 122 extend outwardly beyond the sides of the front cover 112. In other embodiments, however, the actuators 122 may not extend beyond the sides of the front cover 112.

The buffer 120 may comprise any suitable cleaning material for cleaning particulate matter and other materials deposited on the display 104 of the PED 102. For example, in certain embodiments, the buffer 120 may comprise a microfiber cloth material. In other embodiments, the buffer 120 may comprise any suitable material that may clean the display 104 and/or the PED 102 without damage including, for example, suede, cotton, linen, natural and artificial sponge, and the like. In embodiments, the buffer 120 may comprise a material that has increased cleaning ability when wetted with water or a cleaning solution. In further embodiments, the cleaning mechanism 118 may include a squeegee or similar cleaning system in addition to or alternative to the buffer 120.

The cleaning material may itself be relatively resilient or, alternatively, the cleaning material may be placed on a surface of a resilient or spongy material included in a center of the buffer 120. In some embodiments, placing the cleaning material on a resilient or spongy material may provide pressure between the buffer 120 and the PED 102 and/or the display 104, thereby increasing the ability of the buffer 120 to clean the PED 102 and/or the display. In certain embodiments, the portion of the buffer 120 that includes the cleaning material may extend along a full width of the cavity 114 defined by the front cover 112, whereas in other embodiments, it is constrained to an area corresponding to the surface of the display 104.

In certain embodiments, as indicated by arrow 128, the buffer 120 may be translated along the front cover 112 along one or more channels 126. In certain embodiments, the buffer 120 may be translated along the front cover 112 by articulating the actuators 122 along the channels 126. When the case 100 is in a closed configuration, as illustrated in FIG. 2, by translating the buffer 120 along the one or more channels 126, the buffer 120 may be moved across the display 104 of the PED 102, thereby removing (i.e., cleaning) particulate matter and other materials deposited on the display 104.

Rotating the buffer 120 as it is translated along the one or more channels 126 may increase the ability of the buffer 120 to remove particulate matter and other materials from the display 104. Accordingly, the cleaning system 118 may be configured such that when the actuators 122 are rotated (e.g., rotated in the direction of arrow 130), the rod 124 and the buffer 120 also rotate. In this manner, by rotating the actuators 122 while simultaneously translating the actuators 122, rod 124, and buffer 120 along the channels 126, the display may be cleaned more effectively.

In certain embodiments, the channels 126, actuators 122, and/or rod 124 may include an integrated rack and pinion mechanism. For example, as illustrated, the channels 126 may include an integrated rack mechanism disposed therein. A pinion mechanism may be integrated in either the actuators 122 or the rod 124 such that when the actuators 122 are used to translate the buffer 120 along the channels 126, the pinion mechanism engages with the rack mechanism, thereby automatically causing the buffer 120 to rotate in the direction of arrow 130. Including such a rack and pinion mechanism may allow for a rotational buffer 120 without requiring a user to manually rotate the actuators 122.

As illustrated in FIG. 2, the front cover 112 may cover and protect the PED 102 from external damage when the case 100 is in a closed configuration. In alternative embodiments, the front cover 112 may define a window allowing access to the PED 102 and/or the display 104 when the front cover 112 is closed against the back cover 108 about the hinge 116. A top and/or bottom side retractable screen may be affixed to the front cover 112 and be configured to be drawn across the window when the buffer is translated along the channels 126 by actuating the actuators 122. In this manner, the retractable screen may be used to selectively protect and/or access the PED 102 and/or the display 104 when the case 100 is in a closed configuration.

Other arrangements than those specifically described with respect to the embodiment illustrated in FIGS. 1-2 are contemplated. For example, in some embodiments, the buffer 120 may be moved horizontally, or in a landscape direction, rather than vertically, or in a portrait direction, as illustrated. In other embodiments, the actuators 122 may be recessed within the sides of the front cover 112 and/or a single actuator 122 may be utilized. In further embodiments, the holder 106 comprises a sleeve of plastic or other suitable material into which the PED 102 is received, and the sleeve can include an opening sized to provide access to the display 104 when the PED 102 is disposed therein. In still other or further embodiments, the holder 106 can define a recess into which the PED 102 is received, which can be sized to securely retain the PED 102 using, for example, a compression fit mechanism. In such embodiments, an entire front surface of PED 102 may be exposed for cleaning by the buffer 120.

In further various embodiments, the front cover 112 may not define a cavity 114 and/or the buffer 120 may not be not positioned within a cavity 114. In certain embodiments, the holder 106 and/or back cover 108 may include the cleaning mechanism 118. For example, in certain embodiments, the cleaning mechanism 118 may be integrated in the sidewalls of the holder 106 and/or back cover 108.

It will be understood by those having skill in the art that changes may be made to the details of the above-described embodiments without departing from the underlying principles presented herein. For example, the cleaning mechanism 118 may also be integrated into the back cover 108 of the case 100, thereby allowing the back surface of a PED 102 disposed therein to be cleaned. Further, the embodiments of the cleaning mechanism 118 may also be integrated into a stand, a mount, or any other type of accessory configured to receive a PED 102.

In addition, any suitable combination of various embodiments, or the features thereof, is contemplated. Further, any methods disclosed herein may comprise one or more steps or actions for performing the described method. These method steps and/or actions may be interchanged with one another. In other words, unless a specific order of steps or actions is required for proper operation of the embodiment, the order and/or use of specific steps and/or actions may be modified.

Throughout this specification, any reference to “one embodiment,” “an embodiment,” or “the embodiment” means that a particular feature, structure, or characteristic described in connection with that embodiment is included in at least one embodiment. Thus, the quoted phrases, or variations thereof, as recited throughout this specification are not necessarily all referring to the same embodiment. Similarly, it should be appreciated that in the above description of embodiments, various features are sometimes grouped together in a single embodiment, figure, or description thereof for the purpose of streamlining the disclosure. This method of disclosure, however, is not to be interpreted as reflecting an intention that any claim require more features than those expressly recited in that claim. Rather, inventive aspects lie in a combination of fewer than all features of any single foregoing disclosed embodiment. It will be apparent to those having skill in the art that changes may be made to the details of the above-described embodiments without departing from the underlying principles set forth herein.

What is claimed is:

1. A case for a portable electronic device comprising:
a back cover configured to secure the portable electronic device;
a front cover rotationally coupled to the back cover;
a cleaning mechanism integrated into the front cover including a buffer configured to clean a surface of the portable electronic device.

2. The case of claim 1, wherein the buffer comprises a buffer material configured to clean a surface of the portable electronic device.

3. The case of claim 2, wherein the buffer material comprises a microfiber material.

4. The case of claim 2, wherein the buffer material is disposed around a resilient material.

5. The case of claim 2, wherein the buffer is disposed around a rigid rod.

6. The case of claim 5, wherein the cleaning mechanism further includes one or more actuators configured to translate the buffer along one or more channels integrated into the front cover.

7. The case of claim 6, wherein the one or more actuators include a pinion mechanism and the one or more channels include a rack mechanism configured to rotate the buffer as the buffer is translated along the one or more channels.

8. The case of claim 6, wherein the rigid rod includes a pinion mechanism and the one or more channels include a rack mechanism configured to rotate the buffer as the buffer is translated along the one or more channels.

9. The case of claim 6, wherein the buffer is configured to rotate when the one or more actuators are manually rotated by a user.

10. The case of claim 1, wherein the front cover is rotatably coupled to the back cover about a hinge.

11. The case of claim 1, wherein the case is configured to be oriented in a closed configuration, wherein in the closed configuration the front cover is rotated about the hinge against the back cover thereby enclosing a portable electronic device secured to the back cover by the one or more connectors.

12. The case of claim 11, wherein the cleaning mechanism is configured to clean a surface of the portable electronic device when the case is in the closed configuration.

13. The case of claim 12, wherein the surface of the portable electronic device includes a display.

14. The case of claim 12, wherein the buffer is configured to contact the surface of the portable electronic device when the case is in the closed configuration.

15. The case of claim 1, wherein the back cover is configured to secure the portable electronic device using one or more connectors.

16. The case of claim 15, wherein the one or more connectors include one or more resilient straps.

17. The case of claim 16, wherein the one or more resilient straps comprise elastic straps.

18. The case of claim 15, wherein the one or more connectors include one or more rotatable mechanisms configured to rotate the portable electronic device relative to the back cover.

19. The case of claim 18, wherein the one or more rotatable mechanisms include a rotational grommet mechanism.

20. The case of claim 15, wherein the one or more connectors are configured to allow the portable electronic device to selectively detach from the back cover.

21. The case of claim 15, wherein the one or more connectors are configured to secure the portable electronic device using a compression fit mechanism.

22. A case for a portable electronic device comprising:
a back cover configured to secure the portable electronic device;
a front cover having an side rotationally coupled to a side the back cover about a hinge; and
a cleaning mechanism integrated into the front cover including a microfiber buffer configured to clean a surface of the portable electronic device as it is translated one or more channels integrated into the front cover.
